(19) United States
(12) Patent Application Publication
(10) Pub. No.: US 2025/0330086 A1
(43) Pub. Date: Oct. 23, 2025

(54) DIGITAL CONTROL OF A POWER MANAGEMENT CIRCUIT

(71) Applicant: Qorvo US, Inc., Greensboro, NC (US)

(72) Inventors: Baker Scott, San Jose, CA (US); David Edward Reed, Calhan, CO (US); George Maxim, Saratoga, CA (US); Nadim Khlat, Cugnaux (FR); Christopher T. Brown, Sunnyvale, CA (US); Stephen James Franck, Felton, CA (US)

(21) Appl. No.: 19/095,377

(22) Filed: Mar. 31, 2025

Related U.S. Application Data
(60) Provisional application No. 63/636,171, filed on Apr. 19, 2024.

(51) Int. Cl. H02M 3/157; H02M 1/00; H03M 1/10

(52) U.S. Cl. CPC H02M 3/157; H02M 1/0012; H02M 1/0032; H03M 1/1009

(57) ABSTRACT

Systems and method for digital control of a power management circuit are disclosed. In one aspect, a power management circuit may take analog samples of output voltages and currents. These analog samples are converted to digital signals and provided as feedback signals to a digital control and stabilization circuit. The digital control circuit then generates a digital signal that controls a pulse width control circuit, which in turn, controls a switching array of a direct current-to-direct current (DC-DC) converter. The digital control and stabilization circuit may receive or calculate calibration values associated with elements from which the output measurements are taken so as to compensate for process, voltage, temperature and/or other environmental fluctuations in the power management circuit, thereby reducing a need to overdesign the power management circuit and improving settling time and efficiency.

### PRIORITY APPLICATION

The present application is related to U.S. Provisional Patent Application Ser. No. 63/636,171, filed on Apr. 19, 2024, and entitled “DIGITAL CONTROL OF A POWER MANAGEMENT CIRCUIT,” the contents of which are incorporated herein by reference in its entirety.

### BACKGROUND

### I. Field of the Disclosure

The technology of the disclosure relates generally to power management circuits and particularly to a power management circuit that has a direct current-to-direct current (DC-DC) converter.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find ways to reduce power consumption. This pressure has caused the use of power management circuits that can provide a modulated signal to a load, such as a power amplifier. In many cases, the power management circuit employs a direct current-to-direct current (DC-DC) converter that has an analog control and stabilization circuit. Providing a power management circuit that is efficient over a variety of operating conditions provides room for innovation.

### SUMMARY

Aspects disclosed in the detailed description include systems and methods for digital control of a power management circuit. In particular, a power management circuit may take analog samples of output voltages and currents. These analog samples are converted to digital signals and provided as feedback signals to a digital control and stabilization circuit. The digital control circuit then generates a digital signal that controls a pulse width control circuit, which in turn, controls a switching array of a direct current-to-direct current (DC-DC) converter. The digital control and stabilization circuit may receive or calculate calibration values associated with elements from which the output measurements are taken so as to compensate for process, voltage, temperature and/or other environmental fluctuations in the power management circuit, thereby reducing a need to overdesign the power management circuit and improving settling time and efficiency.

In this regard, in one aspect, a power management circuit is disclosed. The power management circuit includes a switch matrix configured to provide an output voltage based on an internal switch configuration, an output filter coupled to the switch matrix, and a sample and hold voltage sensor coupled to the output filter and configured to take an analog voltage measurement. The power management circuit also includes a sample and hold current sensor coupled to the output filter and configured to derive an analog current measurement, a first analog-to-digital converter (ADC) coupled to the sample and hold voltage sensor, a second ADC coupled to the sample and hold current sensor coupled to the sample and hold current sensor, and a digital control and stabilization circuit coupled to the first ADC and the second ADC and configured to generate a signal that controls the switch matrix to produce a desired output voltage for a load.

In another aspect, a communication device is disclosed. The communication device includes a transceiver comprising a power amplifier and a power management circuit coupled to the power amplifier. The power management circuit comprising a switch matrix configured to provide an output voltage based on an internal switch configuration, an output filter coupled to the switch matrix and a sample and hold voltage sensor coupled to the output filter and configured to take an analog voltage measurement. The power management circuit further comprising a first ADC coupled to the sample and hold voltage sensor, a digital control and stabilization circuit coupled to the first ADC and the second ADC and configured to generate a control signal, and a digital pulse width control circuit positioned between the switch matrix and the digital control and stabilization circuit, the digital pulse width control circuit configured to transform the control signal from the digital control and stabilization circuit to a pulse for the switch matrix.

In another aspect, a method for controlling a power management circuit is disclosed. The method includes detecting a voltage at an output node using a voltage sensor, converting an analog voltage signal from the voltage sensor to a digital voltage signal, and passing the digital voltage signal to a digital control and stabilization circuit. The method also includes determining in the digital control and stabilization circuit a control signal for a digital pulse width control circuit and controlling a switch matrix with the digital pulse width control circuit based on the control signal.

### BRIEF DESCRIPTION OF THE DRAWINGS

FIG. 1 is a block diagram of a conventional power management circuit with a direct current-to-direct current (DC-DC) converter using an analog control and stabilization circuit;

FIG. 2 is a block diagram of a power management circuit with a DC-DC converter using a digital control and stabilization circuit according to an exemplary aspect of the present disclosure;

FIG. 3 is a block diagram of the power management circuit of FIG. 2 with additional details about current estimation;

FIG. 4 is a block diagram of an alternate aspect of the power management circuit where still more values used by the digital control and stabilization circuit are estimated instead of provided by a calibration circuit;

FIG. 5A is a block diagram providing details about a sparse analog-to-digital converter (ADC) that may be used in the power management circuit of the present disclosure;

FIG. 5B is a graph showing the steps taken by the ADC of FIG. 5A;

FIG. 6 is a block diagram showing how the pulse width control circuit may provide fractional clock cycle values when controlling the switching array of the DC-DC converter of the present disclosure;

FIG. 7 is a time versus voltage and current graph that illustrates how oversampling may be used to derive certain values used by the digital control and stabilization circuit of the present disclosure;

FIG. 8 is a block diagram of a digital control and stabilization circuit with functional blocks therein;

FIG. 9 is a flowchart illustrating an exemplary process for controlling a power management circuit according to aspects of the present disclosure; and

FIG. 10 is a block diagram of a wireless communication device, which may include the power management circuit of FIGS. 2-4 according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Additionally, to the extent that the term “approximately” is used in the claims, it is herein defined to be within five percent (5%).

Aspects disclosed in the detailed description include systems and methods for digital control of a power management circuit. In particular, a power management circuit may take analog samples of output voltages and currents. These analog samples are converted to digital signals and provided as feedback signals to a digital control and stabilization circuit. The digital control circuit then generates a digital signal that controls a pulse width control circuit, which in turn, controls a switching array of a direct current-to-direct current (DC-DC) converter. The digital control and stabilization circuit may receive or calculate calibration values associated with elements from which the output measurements are taken so as to compensate for process, voltage, temperature and/or other environmental fluctuations in the power management circuit, thereby reducing a need to overdesign the power management circuit and improving settling time and efficiency.

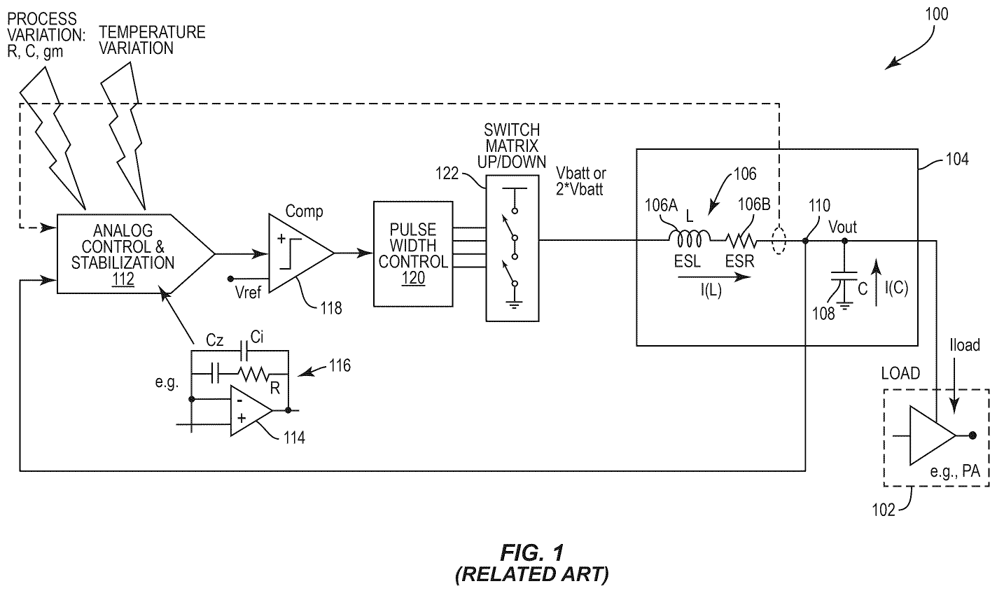

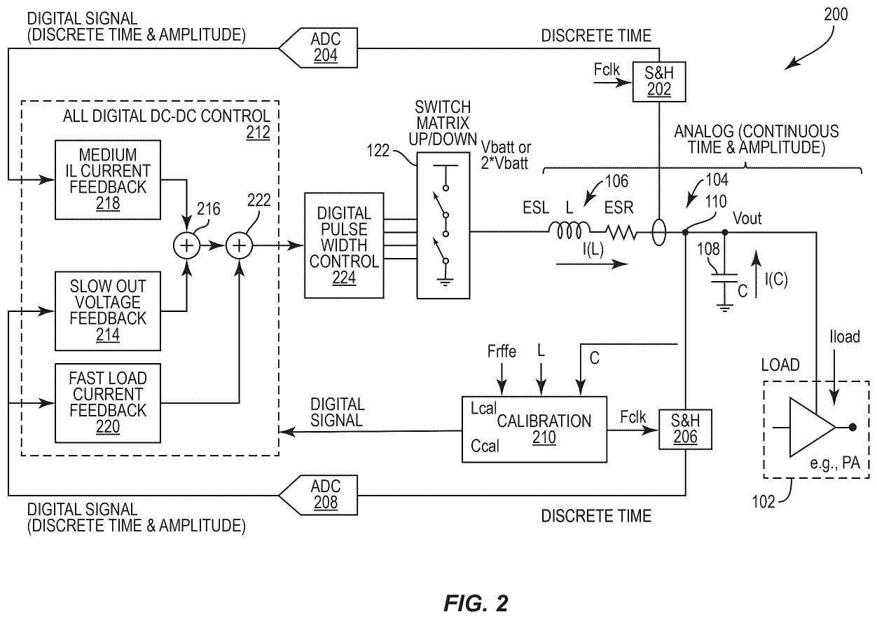

Before addressing aspects of the present disclosure, a brief overview of a conventional power management circuit is provided with reference to FIG. 1. A discussion of aspects of the present disclosure begins below with reference to FIG. 2.

In this regard, FIG. 1 illustrates a power management circuit 100 that provides a supply voltage to a load 102. In many instances, the load 102 may be a power amplifier (e.g., in a transmit chain of a transceiver for a wireless communication device), but power management circuits are not limited to use with power amplifiers. The power management circuit 100 includes an output filter 104, which includes an inductor 106 and a capacitor 108. The inductor 106 has an effective series inductance 106A and an effective series resistance 106B.

A voltage measurement is made at node 110 by a sensor (not shown). Additionally, a current measurement of the current (I(L)) through the inductor 106 may be made by a second sensor (also not shown). Both the measured voltage and the measured current are provided to an analog control and stabilization circuit 112, which may include an operational amplifier 114 with associated circuitry 116. In general, the voltage measurement is part of a relatively slow voltage feedback loop and the current is part of a current feedback loop that is relatively faster than the voltage feedback loop.

The analog control and stabilization circuit 112 provides a control signal to a comparator 118. The control signal is compared to a reference voltage (Vref). Based on the comparison, the comparator 118 provides a signal to a pulse width control circuit 120. The pulse width control circuit 120 controls a switch matrix 122, which selectively couples a battery voltage (Vbatt) or some multiple of a battery voltage (e.g., 2*Vbatt or 3*Vbatt) to the output filter 104 at a duty cycle that causes a desired voltage at the node 110.

In conventional systems, the comparator 118, the pulse width control circuit 120, and the analog control and stabilization circuit 112 are all analog circuits. As such, these circuits are vulnerable to process variations that occur during manufacturing providing inconsistent operation between different ones of the same element. Further, these analog circuits are vulnerable to changes in operation as a function of temperature and/or voltage. The so-called PVT variations may lead to different time constants, which may result in underdamped (and thus less efficient) settling as the output voltage is modulated. One solution is to overdesign the control circuit to assume worst-case operation. This overdesign can lead to slow settling times or other performance tradeoffs.

Exemplary aspects of the present disclosure replace the analog control and stabilization circuit with a digital control and stabilization circuit. To effectuate this, the analog signals measured at the output that form the basis of the feedback loops must be converted to digital signals by analog-to-digital converters (ADCs). Further, the pulse width control circuit may also be digital. Values for the inductance and capacitance of the output filter are provided by a calibration circuit or deduced from oversampling the current and voltage such that the digital pulse width control circuit may be provided a correct duty cycle with which to control the switching array. Because the digital circuitry is less vulnerable to PVT variations and can dynamically adjust to PVT variations, the power management circuit does not need to be overdesigned, the output is not overdamped, and the settling times are within design constraints, resulting in better overall performance. Additionally, tight control of buck-to-boost and boost-to-buck transitions is possible while also eliminating the need for ramp current compensation.

In this regard, FIG. 2 provides a first power management circuit 200. The switch matrix 122 and the output filter 104 are the same as in the power management circuit 100. Likewise, the node 110 is still coupled to a load 102. A first sensor 202 measures current across the inductor 106 using a sample and hold circuit that is triggered by a clock signal (Fclk) thereby forming a discrete time signal. A first ADC 204 converts this measured current to a digital signal thereby forming a discrete time and amplitude signal. Similarly, a second sensor 206 measures a voltage at the node 110 using a sample and hold circuit that is also triggered by the clock signal, thereby forming a discrete time signal. A second ADC 208 converts the measured voltage to a digital signal thereby forming discrete time and amplitude signal.

A calibration circuit 210 receives a reference clock signal (e.g., the clock signal on a radio frequency front end (RFFE) bus (Frffe) that is highly stable) as well as has values (L and C) for the inductor 106 and the capacitor 108. The calibration circuit 210 may generate Fclk from Frffe as well as provide information about L and C to a digital control and stabilization circuit 212. The digital control and stabilization circuit 212 also receives the signals from the first ADC 204 and the second ADC 208.

The digital control and stabilization circuit 212 has a relatively slow voltage feedback input 214, which is summed by summation circuit 216 with a first medium speed current feedback input 218. This sum acts as a stabilizer since it is relatively slow compared to a second fast speed current feedback input 220. A second summation circuit 222 sums the fast current with the sum from summation circuit 216. The digital control and stabilization circuit 212 outputs a signal that is used by a digital pulse width control circuit 224.

It should be appreciated that the current I(L) through the inductor 106 is not the same as Iload. Rather Iload=I(L)+I(C) (the current through the capacitor 108). However, if C of the capacitor 108 is known (as it is from the calibration circuit 210), I(C) may be calculated from changes in the voltage at the node 110. Likewise, if L is known (as it is from the calibration circuit 210), other calculations can be made to convert the output voltage to I(L).

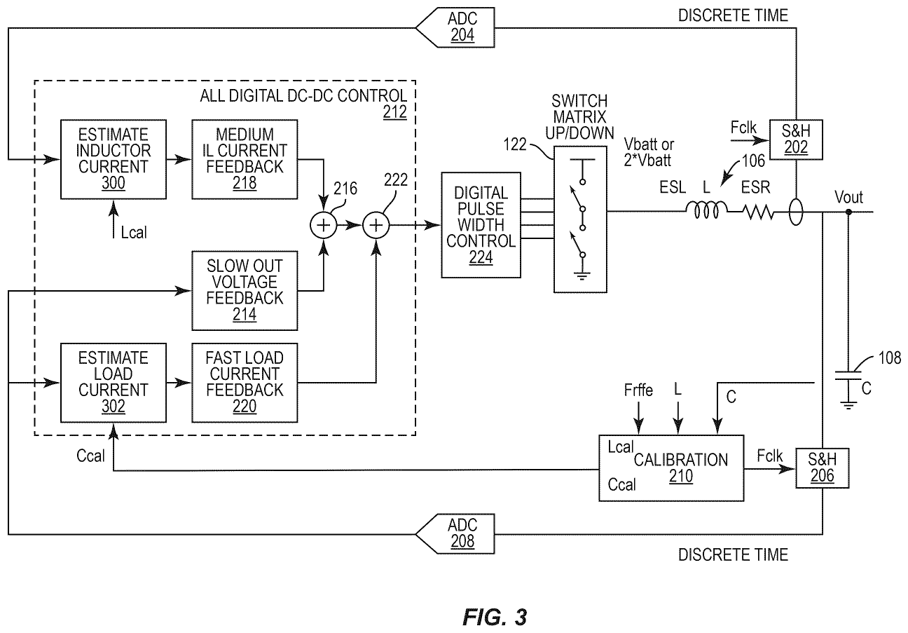

FIG. 3 illustrates current estimation circuits 300 and 302 which use L and C from the calibration circuit 210 that include digital integrator and digital derivatives to find the desired I(L) and I(C) for use in determining the signal for the digital pulse width control circuit 224.

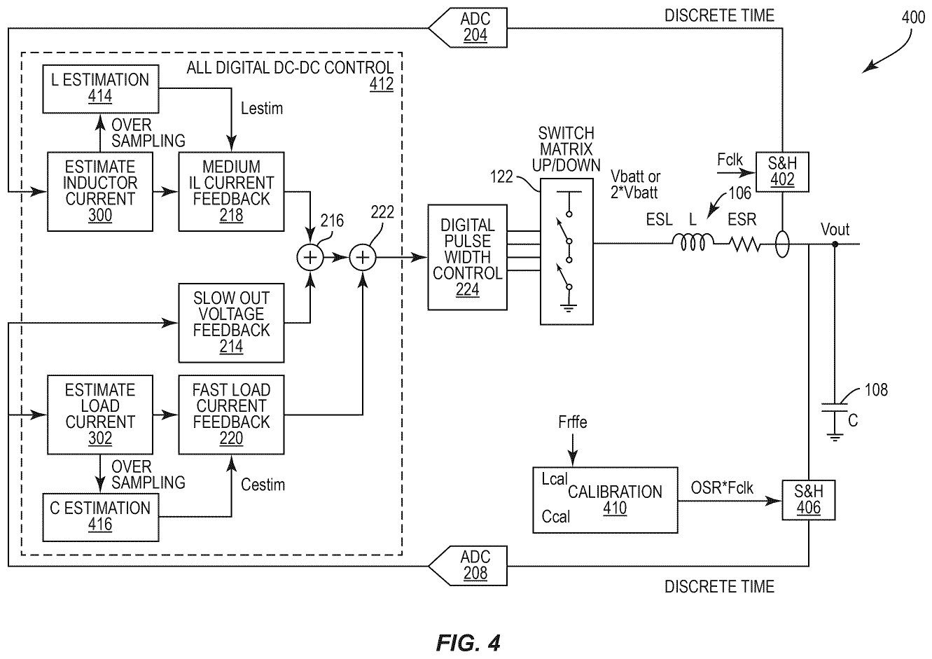

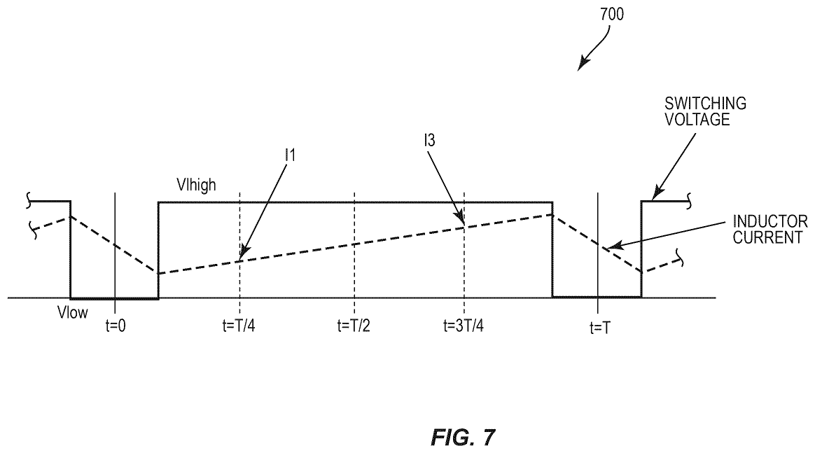

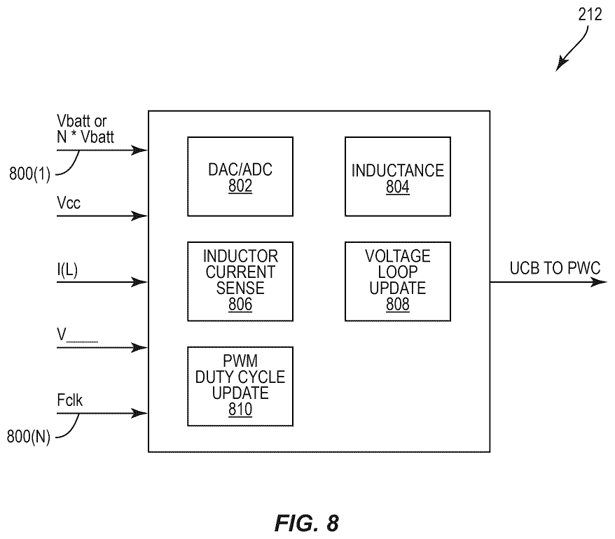

In contrast, FIG. 4 illustrates a power management circuit 400 that uses oversampling to provide sufficient data to estimate L and C without having those values determined and stored in the calibration circuit. Rather, a calibration circuit 410 only generates Fclk and provides oversampled clock signals (OSR*Fclk) to sensors 402, 406. The digital control and stabilization circuit 412 has L estimation circuit 414 and C estimation circuit 416 that use the oversampled information to generate L and C respectively, which are then used in circuits 300, 302. Additional details are provided below with reference to FIGS. 7 and 8.

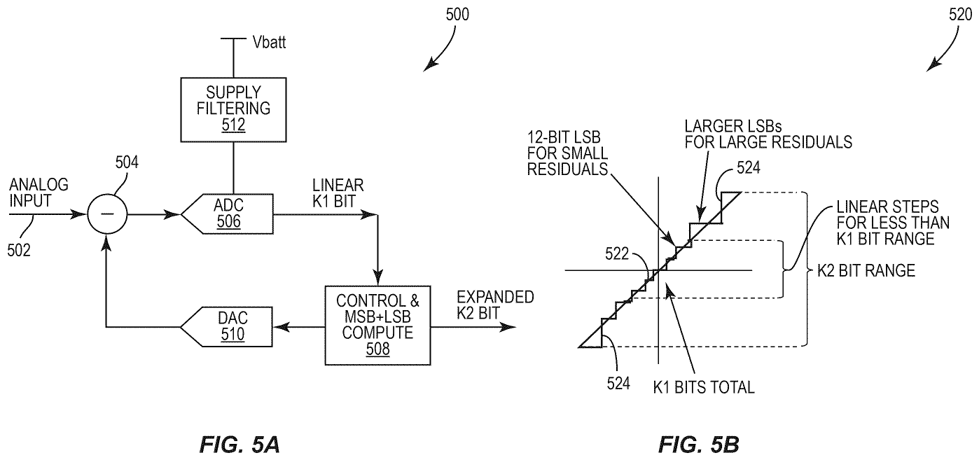

Before addressing some of the calculations done in the digital control and stabilization circuits, some additional details about an ADC 500, which may serve as ADC 204 or 208, are provided with reference to FIG. 5A. It should be appreciated that the digital control and stabilization circuit 212, 412 use digital signals, the creation of which are the function of the ADCs 204 and 208. The ADC 500 needs to be reasonably fast. One option would be a flash-ADC architecture, but fast and high-resolution flash-ADC devices can be hard to implement. It is easier to build a fast, low-bit count flash ADC.

The ADC 500 is a sparse predictive ADC. More specifically, the ADC 500 has a sparse ADC architecture that has a wide range covered by a high number of bits (K2) while using a low number of bits (K1) flash ADC. For a graphical representation of K1, K2, a graph 520 is provided in FIG. 5B, where small steps 522 are taken within the range of K1 and larger steps 524 are taken outside of K1, but within K2. This allows the ADC 500 to take large steps with fewer bits outside a range of interest and takes smaller steps with more bits inside the range of interest. In particular, the ADC 500 includes an input 502 that receives an analog signal input. This analog signal input is combined with a feedback signal at the difference circuit 504. An output of the difference circuit 504 is provided to a low-bit flash ADC 506. A supply filtering circuit 512 is coupled to the low-bit flash ADC 506. The low-bit flash ADC 506 outputs the low bit (K1) signal for a compute circuit 508. The compute circuit 508 outputs the high bit K2 value for use by the digital control and stabilization circuit 212, 412. The compute circuit 508 also provides a signal to a high bit digital to analog converter (DAC) 510, whose analog output is subtracted from the input by the difference circuit 504.

When coupled with oversampling, more sophisticated computations are possible in the digital control and stabilization circuit 212, 412, such as estimating an average, maximum, and minimum of the sampled quantities as well as estimating a time slope. This slope value can be used for estimating values of L and C as better explained below with reference to FIG. 7.

The end goal of the power management circuit of the present disclosure is a digital representation of the control signal for the DC-DC converter. Such digital control value is converted back to continuous time domain to work with the switch matrix 122. More specifically, a digital word is converted into a control pulse for the switch matrix 122. The control pulse establishes the time the switched output voltage is kept at a high value (e.g., Vbatt or N*Vbatt) and at the low value (e.g., 0 V). The DC component of such pulse if the average output voltage Vout, which is used by the load. The higher frequency components of this signal are largely attenuated by the output filter 104.

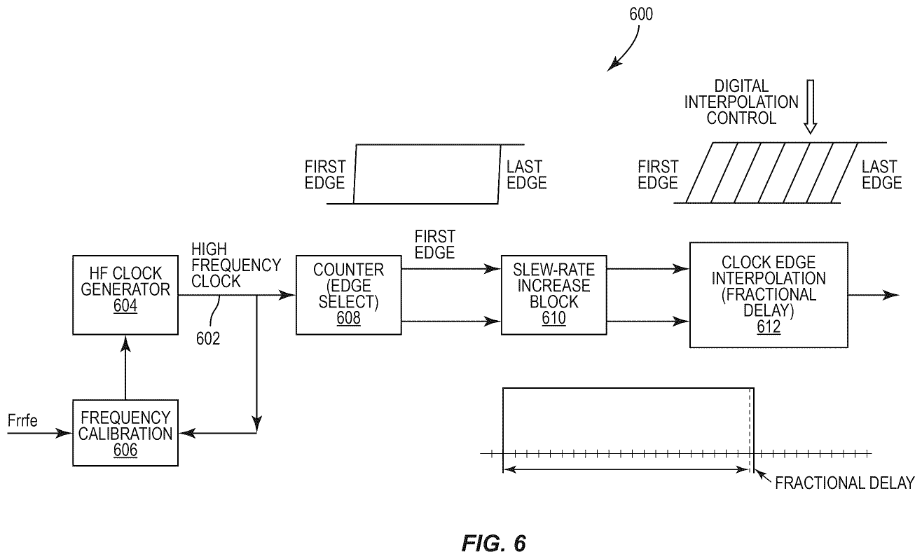

The high resolution of the output voltage necessitates a high resolution for the pulse duty cycle control. There is a high frequency clock signal Frffe which may be used to calibrate Fclk. However, any desired pulse width will have a number of clock cycles, which can be set by a counter. However, the pulse width may require a fractional delay. While there are many ways to get a fractional delay, such as a delta-sigma modulator, aspects of the present disclosure contemplate a mixed signal pulse width modulator-DAC using a counter for the integer delay and an analog edge interpolation circuit for generating the fractional delay as better illustrated in FIG. 6. Specifically, FIG. 6 illustrates a pulse width control circuit 600 that may be the digital pulse width control circuit 224.

The pulse width control circuit 600 generates a high frequency clock signal 602 with a high frequency clock generator 604. The high frequency clock generator 604 receives a calibrated clock signal from a frequency calibration circuit 606, which may be the calibration circuit 210. The frequency calibration circuit 606 receives the tightly controlled clock signal Frffe and a feedback signal equal to the high frequency clock signal 602 to control the high frequency clock generator 604.

The high frequency clock signal 602 is provided to a counter 608 that counts an edge to determine a number of clock cycles for the desired pulse. The counter 608 also provides a first edge and a second edge to an optional slew rate increase circuit 610. The two edges are converted to analog quantities in analog clock edge interpolation circuit 612, which can use weighted DAC techniques and then a weighted summation of the two quantities can be performed to develop the interpolated clock edge. This interpolation of clock edges is based on the fact that a finite slew rate of the edges is present. If the original clock edge speed is too high, the optional slew rate increase circuit 610. The time length of the edge slew rate is equal to or larger than the time interpolation range. The edge created by the analog clock edge interpolation circuit 612 is used to define the ending of the pulses.

FIG. 7 illustrates how the over-sampling may be used to help provide additional information. For example, since both samples are taken at the output node 110, instant voltage and current can be found and plotted against time, as shown in FIG. 7. The graph 700 shows voltage (V) and current (I(L)) at times t=0, t=T/4, t=T/2, t=3T/4, and t=T (where T is the period of the clock signal). The slope of the current can be found by using two spaced out samples 702, 704. With the slope of the current known and Fclk also known, the inductance can be calculated, where dV is also known:

$$L = \frac{dV}{( 2 Fclk * ( I 3 - I 1 )} .$$

By calculating L in this manner, the calibration circuit 210 may be simplified. Further, the max and min currents can also be computed. In a similar fashion, if multiple samples are taken for the voltage on the output capacitance, the slope of the time domain variation of the voltage can be computed, which in turn can be used to estimate the value of C. In such case, dI may need to be known.

To assist in the calculations, the digital control and stabilization circuit 212 may have logical blocks, which may be circuit based as illustrated in FIG. 8 or may be a microprocessor with software stored in memory (not shown explicitly). More specifically, the digital control and stabilization circuit 212 includes multiple inputs 800(1)-800(N), which may, for example, be Vbatt and/or N*Vbatt, a desired target voltage Vtar, I(L), a measured output voltage Vcc, the clock signal Fclk, and the like. Interior circuits (or software as mentioned above) may be a DAC/ADC calculation circuit 802, an inductance estimation circuit 804, an inductor current sense circuit 806, a voltage loop update circuit 808, and a PWM duty cycle update circuit 810.

In an exemplary aspect, the DAC/ADC calculation circuit 802 may calculate dn=2*Xₙ₋₁−Xₙ₋₂, where Xₙ=dn+ADCn, which may be used for Vcc/Vbatt and I(L).

In an exemplary aspect, the inductance estimation circuit 804 may calculate L as described above, where for dc<0.5, dV=(Vcc−Vlow) and for dc>0.5, dV=(Vhigh−Vcc).

In an exemplary aspect, the inductor current sense circuit 806 may calculate I(L)=I(L)+(Vbatt*dcB−Ils*Re-Vcc)/(Fclk*L), where dcB is the output signal to the digital pulse width control circuit 224.

In an exemplary aspect, the voltage loop update circuit 808 may calculate Acc=Acc+(Vtar−Vcc); where Itar=Ki*Acc+Kp*(Vtar−Vcc) and Imin≤Itar≤I max and update Acc when limiting scaled Imax=Imax*(L*Fclk).

In an exemplary aspect, the PWM duty cycle update circuit 810 may calculate dcB=Vcc/Vbatt+(Itar−I(L))*(L*Fclk/Vbatt), where ADC Vref=Vbatt to avoid a divide by Vbatt situation.

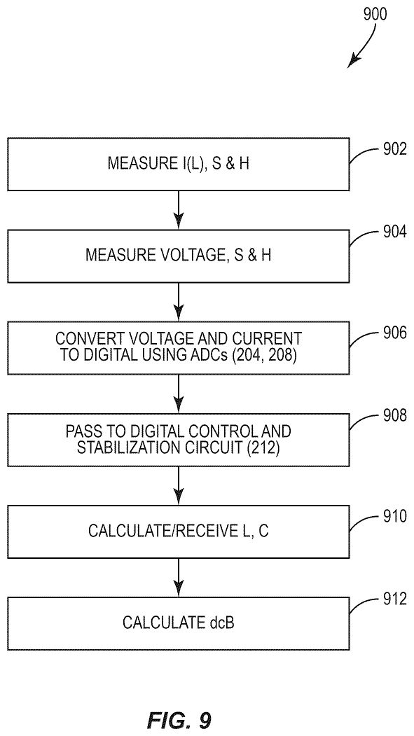

FIG. 9 provides a flowchart of a process 900 for using the power management circuits of the present disclosure. Specifically, the current at the inductor 106 is measured with a sample and hold circuit (block 902). The voltage at the node 110 is measured with a sample and hold circuit (block 904). The measured voltage and current are converted to digital using ADCs 204, 208 (block 906). The digital values are passed to the digital control and stabilization circuit 212 (block 908). The digital control and stabilization circuit 212 receives (from calibration circuit 210) or calculates L and C (block 910) and uses these values to calculate dcB (block 912) to control the digital pulse width control circuit 224.

The systems and methods for digital control of a power management circuit, according to aspects disclosed herein, may be provided in or integrated into any processor-based device that uses a variable load. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

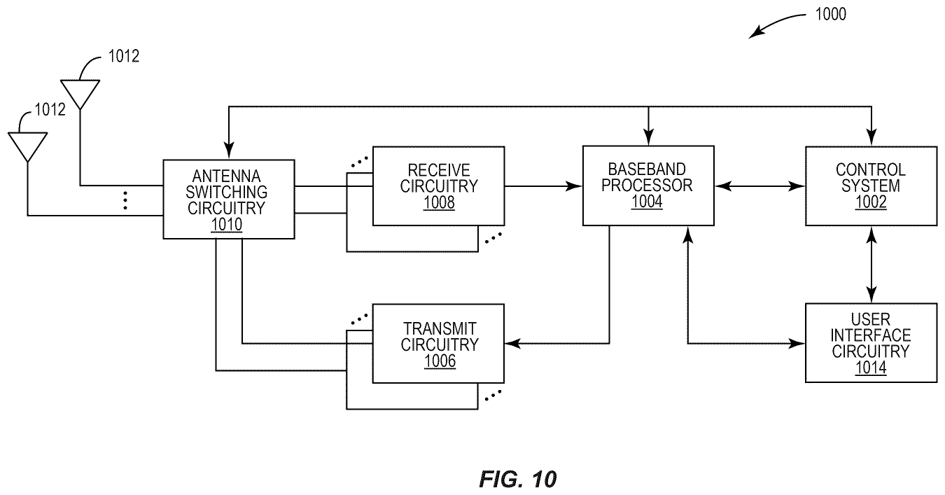

FIG. 10 is a schematic diagram of an exemplary communication device 1000 wherein the power management circuits of the present disclosure can be provided. Herein, the communication device 1000 can be any type of communication devices, such as those listed above as well as access points, base stations (e.g., eNB or gNB), and any other type of wireless communication devices that support wireless communications, such as cellular, wireless local area network (WLAN), Bluetooth, Ultra-wideband (UWB), and near field communications.

More particularly, the communication device 1000 will generally include a control system 1002, a baseband processor 1004, transmit circuitry 1006, receive circuitry 1008, antenna switching circuitry 1010, multiple antennas 1012, and user interface circuitry 1014. In a non-limiting example, the control system 1002 can be a field-programmable gate array (FPGA) or an application-specific integrated circuit (ASIC), as an example. In this regard, the control system 1002 can include at least a microprocessor(s), an embedded memory circuit(s), and a communication bus interface(s). The receive circuitry 1008 receives radio frequency signals via the antennas 1012 and through the antenna switching circuitry 1010 from one or more base stations. A low noise amplifier and a filter of the receive circuitry 1008 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 1004 processes the digitized received signal to extract the information or data bits conveyed in the received signal. This processing typically comprises demodulation, decoding, and error correction operations. The baseband processor 1004 is generally implemented in one or more digital signal processors (DSPs) and ASICs.

For transmission, the baseband processor 1004 receives digitized data, which may represent voice, data, or control information, from the control system 1002, which it encodes for transmission. The encoded data is output to the transmit circuitry 1006, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 1012 through the antenna switching circuitry 1010 to the antennas 1012. The multiple antennas 1012 and the replicated transmit and receive circuitries 1006, 1008 may provide spatial diversity. Modulation and processing details will be understood by those skilled in the art. The power amplifier may be have a supply voltage generated by the power management circuits of the present disclosure.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A power management circuit comprising:
a switch matrix configured to provide an output voltage based on an internal switch configuration;
an output filter coupled to the switch matrix;
a sample and hold voltage sensor coupled to the output filter and configured to take an analog voltage measurement;
a sample and hold current sensor coupled to the output filter and configured to derive an analog current measurement;
a first analog-to-digital converter (ADC) coupled to the sample and hold voltage sensor;
a second ADC coupled to the sample and hold current sensor coupled to the sample and hold current sensor; and
a digital control and stabilization circuit coupled to the first ADC and the second ADC and configured to generate a signal that controls the switch matrix to produce a desired output voltage for a load.

2. The power management circuit of claim 1, further comprising a digital pulse width control circuit positioned between the switch matrix and the digital control and stabilization circuit, the digital pulse width control circuit configured to transform the signal from the digital control and stabilization circuit to a pulse for the switch matrix.

3. The power management circuit of claim 1, wherein the first ADC comprises a sparse ADC.

4. The power management circuit of claim 1, wherein the sample and hold current sensor is configured to measure current in an inductor in the output filter.

5. The power management circuit of claim 1, wherein the digital control and stabilization circuit is further configured to calculate a fast current feedback value based on the analog voltage measurement.

6. The power management circuit of claim 1, further comprising a calibration circuit configured to store an inductance value and a capacitor value associated with the output filter and provide the inductance value and the capacitor value to the digital control and stabilization circuit.

7. The power management circuit of claim 1, wherein the sample and hold voltage sensor is configured to oversample a voltage for the analog voltage measurement.

8. The power management circuit of claim 7, wherein the sample and hold current sensor is configured to oversample a measurement for the analog current measurement.

9. The power management circuit of claim 8, wherein the digital control and stabilization circuit is configured to estimate an inductance associated with the output filter from an inductor current slope.

10. The power management circuit of claim 2, wherein the digital pulse width control circuit is configured to calculate a fractional cycle delay with a delta sigma circuit.

11. The power management circuit of claim 2, wherein the digital pulse width control circuit is configured to calculate a fractional cycle delay with an edge interpolation circuit.

12. The power management circuit of claim 1, wherein the sample and hold voltage sensor is configured to generate one sample per each clock cycle.

13. The power management circuit of claim 1, wherein the sample and hold voltage sensor is configured to generate multiple cycles per each clock cycle.

14. A communication device comprising:
a transceiver comprising a power amplifier and
a power management circuit coupled to the power amplifier, the power management circuit comprising:
a switch matrix configured to provide an output voltage based on an internal switch configuration;
an output filter coupled to the switch matrix;
a sample and hold voltage sensor coupled to the output filter and configured to take an analog voltage measurement;
a first analog-to-digital converter (ADC) coupled to the sample and hold voltage sensor;
a digital control and stabilization circuit coupled to the first ADC and configured to generate a control signal; and
a digital pulse width control circuit positioned between the switch matrix and the digital control and stabilization circuit, the digital pulse width control circuit configured to transform the control signal from the digital control and stabilization circuit to a pulse for the switch matrix.

15. The communication device of claim 14, wherein the digital control and stabilization circuit is configured to receive inductor current and output voltage feedback together with output capacitance current feedback from the output filter.

16. The communication device of claim 14, wherein the ADC comprises a sparse predictive ADC architecture.

17. The communication device of claim 16, wherein the ADC comprises a flash low resolution ADC with small range.

18. The communication device of claim 14, wherein the digital control and stabilization circuit is further configured to calculate a fast current feedback value based on the analog voltage measurement.

19. The communication device of claim 14, further comprising a calibration circuit configured to store an inductance value and a capacitor value associated with the output filter and provide the inductance value and the capacitor value to the digital control and stabilization circuit.

20. A method for controlling a power management circuit, comprising:
detecting a voltage at an output node using a voltage sensor;
converting an analog voltage signal from the voltage sensor to a digital voltage signal;
passing the digital voltage signal to a digital control and stabilization circuit;
determining in the digital control and stabilization circuit a control signal for a digital pulse width control circuit; and
controlling a switch matrix with the digital pulse width control circuit based on the control signal.
